(19) United States
(12) Patent Application Publication
(10) Pub. No.: US 2026/0107460 A1
(43) Pub. Date: Apr. 16, 2026

(54) ERASABLE PROGRAMMABLE NON-VOLATILE MEMORY

(71) Applicant: eMemory Technology Inc., Hsin-Chu (TW)

(72) Inventor: Hsueh-Wei CHEN, Hsinchu County (TW)

(21) Appl. No.: 19/357,845

(22) Filed: Oct. 14, 2025

Related U.S. Application Data
(60) Provisional application No. 63/706,767, filed on Oct. 14, 2024.

(51) Int. Cl. H10B 41/30; G11C 5/06; G11C 16/04; G11C 16/10; G11C 16/14; H10B 41/70; H10D 1/66; H10D 30/01; H10D 30/60; H10D 30/68; H10D 62/10; H10D 62/60

(52) U.S. Cl. CPC H10B 41/30; G11C 5/063; G11C 16/0416; G11C 16/102; G11C 16/14; H10B 41/70; H10D 1/66; H10D 30/601; H10D 30/68; H10D 62/124; H10D 62/60; H10D 30/0227; H10D 30/0411

(57) ABSTRACT

A non-volatile memory cell includes a floating gate transistor, a MOS capacitor and a plate capacitor. A first drain/source terminal of the floating gate transistor is connected to a source line, and a second drain/source terminal of the floating gate transistor is connected to a bit line. A first terminal of the MOS capacitor is connected to a floating gate of the floating gate transistor, and a second terminal of the MOS capacitor is connected to a control line. A first terminal of the plate capacitor is connected to the floating gate of the floating gate transistor, and a second terminal of the plate capacitor is connected to an assist line.

This application claims the benefit of U.S. provisional application Ser. No. 63/706,767, filed Oct. 14, 2024, the subject matters of which is incorporated herein by reference.

### FIELD OF THE INVENTION

The present invention relates to a non-volatile memory, and more particularly to an erasable programmable non-volatile memory and associated memory cell.

### BACKGROUND OF THE INVENTION

As is well known, non-volatile memories (MVMs) have been widely used in a variety of electronic devices such as SD cards or solid state drives (SSDs). Generally, an erasable programmable non-volatile memory includes a memory cell array. The memory cell array includes a plurality of memory cells.

For example, each memory cell includes a floating gate transistor. The floating gate of the floating gate transistor can store hot carriers. The storage state of the floating gate transistor can be determined according to the amount of stored carriers. For example, the carriers are electrons or holes.

Nowadays, by using the CMOS manufacturing process, IO devices capable of withstanding higher voltages and core devices capable of withstanding lower voltages can be formed on a single piece of semiconductor substrate. The core devices are also referred to as low voltage devices (or LV devices) such as LV P-type transistors and LV N-type transistors. The IO devices are also referred as medium voltage devices (or MV devices) such as MV P-type transistors and MV N-type transistors. Since the gate dielectric layer of the LV device is thinner, the LV device is only able to withstand the lower voltage stress. However, the operation speed of the LV device is faster. The gate dielectric layer of the MV device is thick enough to withstand the higher voltage stress. However, the operation speed of the MV device is slower.

When a program action or an erase action is performed on the memory cell, the memory cell needs to receive a higher program voltage or a higher erase voltage. For example, the erase voltage is approximately in the range between 14V and 19V, and the program voltage is approximately in the range between 7.5V and 9V. In other words, the transistors in the memory cell (e.g., including the floating gate transistor) are MV devices. Consequently, the memory cell needs to comply with the design rules of the MV device. For example, the gate channel length of the transistor in the MV device is at least 0.45 μm.

Due to the design rules of the MV device, the size of the conventional memory cell is usually too large.

### SUMMARY OF THE INVENTION

An erasable programmable non-volatile memory comprises a first memory cell. The first memory cell comprises a semiconductor substrate, an isolation structure, a first well region, a second well region, a gate structure, a spacer, a first merged doped region, a second merged doped region, a third merged doped region, a first pocket region, a second pocket region, a metal layer, a first MOS capacitor and a first plate capacitor. The isolation structure is formed on the semiconductor substrate. A surface of the semiconductor substrate is divided into a first region and a second region by the isolation structure. The first well region is formed under a surface of the first region of the semiconductor substrate. The second well region is formed under a surface of the second region of the semiconductor substrate. The gate structure is formed on the surface of the first region and the surface of the second region. The spacer is formed on a sidewall of the gate structure. The first merged doped region is formed under the surface of the first region. The first merged doped region is located beside a first side of the gate structure. The second merged doped region is formed under the surface of the first region. The second merged doped region is located beside a second side of the gate structure. The first pocket region is formed in the first well region. The first pocket is contacted with the first merged doped region. The second pocket region is formed in the first well region. The second pocket is contacted with the second merged doped region, and the first pocket region and the second pocket region are located between the first merged doped region and the second merged doped region. The third merged doped region is formed under the surface of the second region. The metal layer is formed over the gate structure. A vertical projection area of the metal layer covers the gate structure. A first source line is electrically connected with the first merged doped region. A first bit line is electrically connected with the second merged doped region. A first control line is electrically connected with the third merged doped region. An assist line is connected with the metal layer. A first terminal of the first MOS capacitor is electrically connected with the gate structure, and a second terminal of the first MOS capacitor is electrically connected with first control line. A first terminal of the first plate capacitor is electrically connected with the gate structure, and a second terminal of the first plate capacitor is electrically connected with the assist line. The first merged doped region, the gate structure and the second merged doped region are collaboratively formed as a first floating gate transistor. The gate structure and the third merged doped region are collaboratively formed as the first MOS capacitor. The gate structure and the metal layer are collaboratively formed as the first plate capacitor.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1K schematically illustrate the steps of a method of manufacturing a memory cell according to a first embodiment of the present invention;

FIG. 1L is a schematic equivalent circuit diagram of the memory cell according to the first embodiment of the present invention;

FIG. 2 is a schematic perspective view illustrating the structure of a memory cell according to a second embodiment of the present invention;

FIG. 3 is a schematic perspective view illustrating the structure of a memory cell according to a third embodiment of the present invention;

FIG. 4A and FIG. 4B are a schematic cross-sectional view and a schematic top view illustrating the structure of a memory cell according to a fourth embodiment of the present invention;

FIG. 5A and FIG. 5B are a schematic cross-sectional view and a schematic equivalent circuit diagram of a memory cell according to a fifth embodiment of the present invention;

FIG. 6 is a schematic cross-sectional view of a memory cell according to a sixth embodiment of the present invention;

FIG. 7A is a bias voltage table illustrating the bias voltages for performing a program action, an erase action and a read action on the memory cell of the embodiments of the present invention;

FIG. 7B and FIG. 7C are schematic circuit diagram of performing the program actions on the memory cell;

FIG. 7D and FIG. 7E are schematic circuit diagrams of performing the erase action on the memory cell;

FIGS. 7F and 7G are schematic circuit diagrams of performing the read action on the memory cell;

FIG. 8A is a schematic circuit diagram illustrating a first example of a memory cell array and shows the bias voltages for performing the program action on the memory cell array of the first example;

FIG. 8B shows the bias voltages for performing the erase action on the memory cell array of the first example;

FIG. 8C shows the bias voltages for performing the read action on the memory cell array of the first example;

FIG. 9A is a schematic circuit diagram illustrating a second example of a memory cell array and shows the bias voltages for performing the program action on the memory cell array of the second example;

FIG. 9B shows the bias voltages for performing the erase action on the memory cell array of the second example; and

FIG. 9C shows the bias voltages for performing the read action on the memory cell array of the second example.

### DETAILED DESCRIPTION OF PREFERRED EMBODIMENTS

As mentioned above, in the CMOS manufacturing process, MV devices and LV devices can be formed on a single piece of semiconductor substrate. The present invention provides a memory cell included in the memory cell array of an erasable programmable non-volatile memory. By using the manufacturing method including a medium voltage (MV) production procedure and a low voltage (LV) production procedure, the memory cell is manufactured. That is, for designing the structure of the memory cell of the present invention, a portion of the structure is manufactured according to the design rule of the MV device, and another portion of the structure is manufactured according to the design rule of the LV device. Consequently, the size of the memory cell will be reduced. For well understanding the concepts of the present invention, some embodiments of the memory cell will be described as follows.

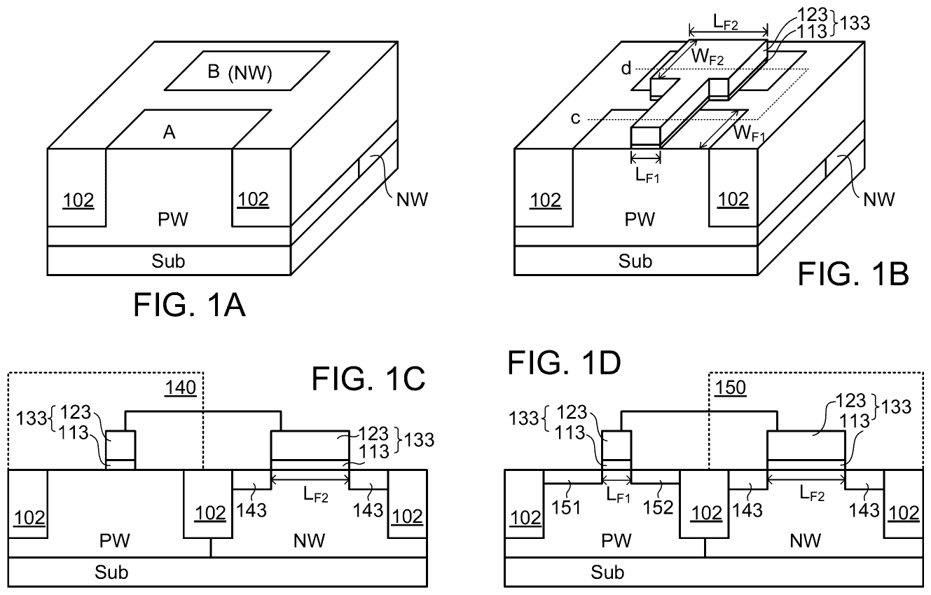

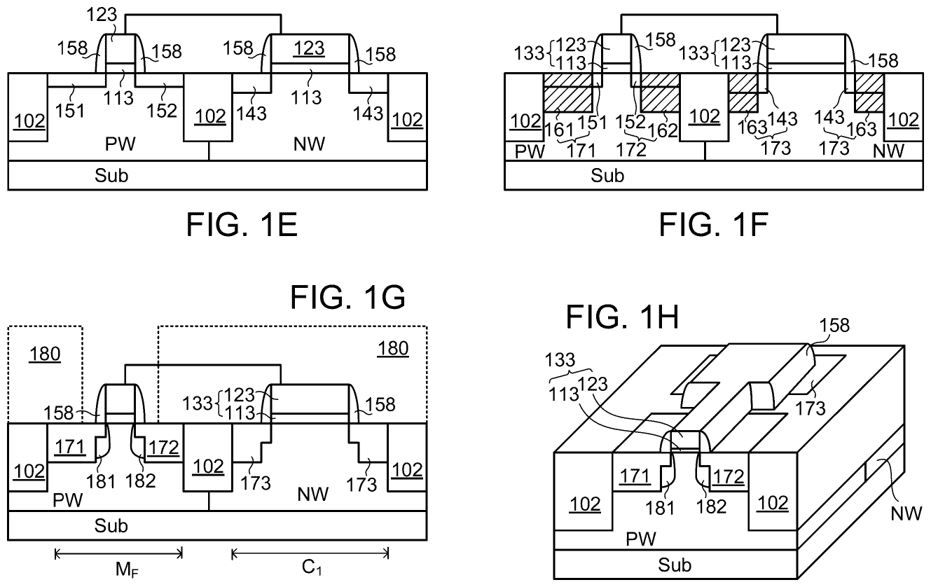

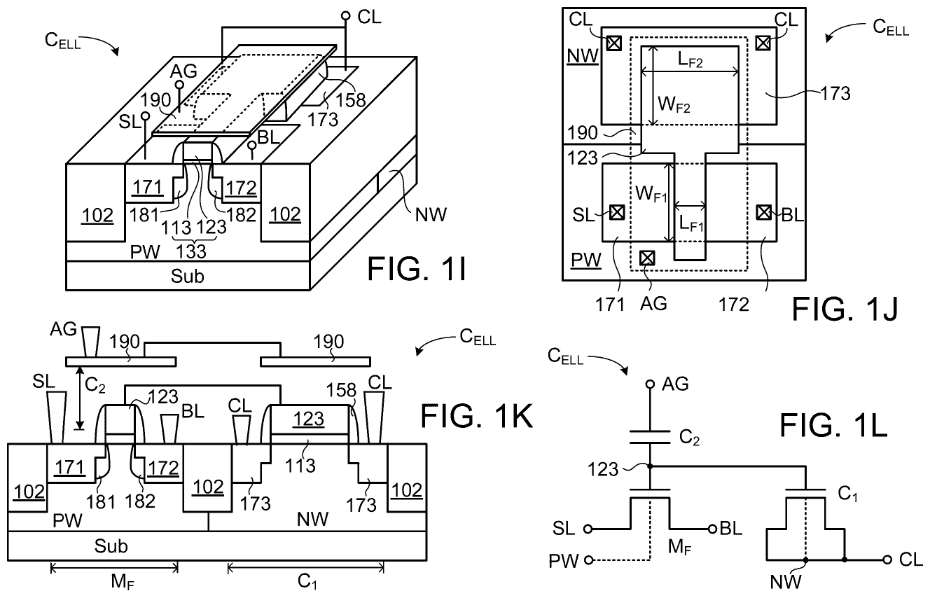

FIGS. 1A to 1K schematically illustrate the steps of a method of manufacturing a memory cell according to a first embodiment of the present invention. FIG. 1L is a schematic equivalent circuit diagram of the memory cell according to the first embodiment of the present invention. The memory cell of the present is an erasable programmable non-volatile memory cell.

As shown in FIG. 1A, an isolation structure forming step is performed. An isolation structure 102 is formed on a semiconductor substrate Sub. Due to the isolation structure 102, a region A and a region B are defined. The semiconductor substrate Sub is covered by the isolation structure 102. The surface of the semiconductor substrate Sub corresponding to the region A and the region B is exposed. For example, the isolation structure 102 is a shallow trench isolation (STI) structure. In this embodiment, a memory cell is constructed on the region A and the region B.

Then, plural well regions forming step are performed. Consequently, a first well region is formed under the surface of the semiconductor substrate Sub corresponding to the region A, and a second well region is formed under the surface of the semiconductor substrate Sub corresponding to the region B. For example, the first well region is a P-well region PW, the second well region is an N-well region NW, and the semiconductor substrate Sub is a P-type semiconductor substrate.

Then, a gate structure forming step is performed. As shown in FIG. 1B, a gate structures 133 is formed. The gate structure 133 includes a gate dielectric layer 113 and a polysilicon gate layer 123. The gate dielectric layer 113 is contacted with the surface of the P-well region PW, the surface of the isolation structure 102 and the surface of the N-well region NW. The polysilicon gate layer 123 is formed on the gate dielectric layer 113. That is, the gate structure 133 is formed on the surface of the region A, and the gate structure 133 is externally extended to cover the surface of the region B through the surface of the isolation structure 102.

In this embodiment, the width of the gate structure 133 covering the region A is W_{F1} and the length of the gate structure 133 covering the region A is L_{F1}. The width of the gate structure 133 covering the region B is W_{F2} and the length of the gate structure 133 covering the region B is L_{F2}. For example, the width W_{F1} is equal to the width W_{F2}, and the length L_{F1} is smaller than the length L_{F2}. Consequently, (L_{F2}×W_{F2}) is greater than (L_{F1}×W_{F1}). That is, the overlapping area (L_{F2}×W_{F2}) between the gate structure 133 and the region B is greater than the overlapping area (L_{F1}×W_{F1}) between the gate structure 133 and the region A.

According to the present invention, the shape of the gate structure 133 can also be modified as long as the overlapping area between the gate structure 133 and the area B is greater than the overlapping area between the gate structure 133 and the area A. For example, the width W_{F1} is smaller than the width W_{F2} and length L_{F1} is smaller than the length L_{F2}, too.

The subsequent steps of the manufacturing process of the memory cell will be illustrated. In FIGS. 1C, 1D, 1E and 1F, the cross-sectional views taken along the dotted line cd shown in FIG. 1B will be used to introduce the subsequent steps of the manufacturing process of the memory cell.

Please refer to FIG. 1C. The gate structure 133 in the region A is covered with a mask 140 shown in dotted lines. The region B is not covered with the mask 140, and the gate structure 133 corresponding to the region B and its surrounding areas are exposed. For example, the mask 140 is formed of a photoresist layer. As shown in FIG. 1B, the memory cell has a single polysilicon gate layer 123. In FIG. 1C, two polysilicon gate layers 123 are connected with each other by a solid line and represented as the same polysilicon gate layer.

Then, a lightly doped drain process (LDD process) in the MV production procedure is performed. Consequently, n-type lightly doped drain regions (n-LDD regions) 143 is formed under the surface of the region B and arranged around the gate structure 133. As shown in FIG. 1C, a channel length below the gate structure 133 is L_{F2}.

Please refer to FIG. 1D. After the mask 140 is removed, the gate structure 133 in the region B is covered with the mask 150. The region A is not covered with the mask 150, and the gate structure 133 corresponding to the region A and its surrounding areas are exposed. For example, the mask 150 is formed of a photoresist layer.

Then, an LDD process in the LV production procedure is performed. Consequently, n-type lightly doped drain regions (n-LDD regions) 151 and 152 are formed under the surface of the semiconductor substrate Sub uncovered by the mask 150 and the gate structure 133. The n-LDD regions 151 and 152 are formed under the surface of the region A and respectively located beside the two sides of the gate structure 133. As shown in FIG. 1D, a channel length between the two n-LDD regions 151 and 152 and under the gate structure 133 is L_{F1}. Furthermore, the doping concentrations of the n-LDD regions 151 and 152 are equal, and the doping depths of the n-LDD regions 151 and 152 are equal.

According to the present invention, the first LDD process belongs to the MV production procedure. The second LDD process belongs to the LV production procedure. In other words, the doping concentration of the n-LDD regions 143 is less than the doping concentrations of the n-LDD regions 151 and 152, and the doping depths of the n-LDD regions 151 and 152 are shallower than the doping depth of the n-LDD regions 143.

Please refer to FIG. 1E. After the mask 150 is removed, a spacer 158 is formed on the sidewall of the gate structure 133. The spacer 158 is contacted with the sidewall of the gate structure 133.

Please refer to FIG. 1F. Then, an n-type ion implantation process in the MV production procedure is performed on the surface of the semiconductor substrate Sub by using the gate structures 133 and the spacer 158 as masks. Consequently, two n-type ion implantation regions 161 and 162 shown in oblique lines are formed on two sub-regions of the region A uncovered by the gate structures 133 and the spacer 158, and an n-type ion implantation region 163 shown in oblique lines is formed on the region B uncovered by the gate structure 133 and the spacer 158. Especially, the n-type ion implantation regions 161, 162 and 163 have the highest doping concentration. That is, the dopant concentrations of the n-type ion implantation regions 161, 162 and 163 are greater than the dopant concentrations of the n-LDD regions 151, 152 and 143.

Please refer to FIG. 1F again. Then, in the region A, the n-LDD region 151 and the n-type ion implantation region 161 are collaboratively formed as a merged n-doped region 171. The merged n-doped region 171 is formed under the surface of the semiconductor substrate Sub and located beside the first side of the gate structure 133. Similarly, the n-LDD region 152 and the n-type ion implantation region 162 are collaboratively formed as a merged n-doped region 172. The merged n-doped region 172 is formed under the surface of the semiconductor substrate Sub and located beside the second side of the gate structure 133. In the region B, the n-LDD region 143 and the n-type ion implantation region 163 are collaboratively formed as a merged n-doped region 173. The merged n-doped region 173 is formed under the surface of the semiconductor substrate Sub and located beside the gate structure 133. In the region A, the n-LDD region 151 is located below the spacer 158 beside the first side of the gate structure 133, and the n-LDD region 152 is located below the spacer 158 beside the second side of the gate structure 133. In the region B, the n-LDD region 143 is located below the spacer 158 beside the gate structure 133.

Please refer to FIG. 1G. A mask 180 is formed to cover the surface of the semiconductor substrate Sub, exposing the gate structure 133 and the spacer 158 in the region A, and also exposing a portion of the merged n-doped region 171 and a portion of the merged n-doped region 172 beside the spacer 158. For example, the mask 180 is formed of a photoresist layer.

Then, a pocket implantation process in the LV production procedure is performed. Consequently, p-type pocket regions 181 and 182 are formed in the P-well region PW. The p-type pocket regions 181 and 182 are located between two merged n-doped regions 171 and 172, the p-type pocket region 181 is contacted with the merged n-doped region 171, the p-type pocket region 182 is contacted with the merged n-doped region 172, and the two p-type pocket regions 181 and 182 are not contacted with each other. Furthermore, the pocket implantation process may also be referred to as the halo implantation process, and the p-type pocket regions 181 and 182 may also be referred to as the halo regions.

The perspective view of the structure of FIG. 1G after removing the mask 180 is shown in FIG. 1H.

In the region A, the P-well region PW, the gate structure 133 and the merged n-doped regions 171 and 172 are collaboratively formed as a floating gate transistor M_{F}, and the polysilicon gate layer 123 is the floating gate of the floating gate transistor M_{F}. In the region B, the N-well region NW, the gate structure 133, and the merged n-doped region 173 are collaboratively formed as a MOS capacitor C₁. The MOS capacitor C₁ is an n-type capacitor. Furthermore, the floating gate transistor M_{F} is an n-type floating gate transistor and constructed in the P-well region PW. That is, the body terminal of the floating gate transistor M_{F} is connected to the P-well region PW.

Please refer to FIG. 1I, FIG. 1J and FIG. 1K. FIG. 1J is a schematic top view of the structure shown in FIG. 1I. FIG. 1K is a schematic cross-sectional view of the structure shown in FIG. 1I. Then, a metal layer 190 is formed over the polysilicon gate layer 123 of the gate structure 133. The size of the metal layer 190 is greater than the size of the polysilicon gate layer 123. Consequently, the vertical projection area of the metal layer 190 completely covers the polysilicon gate layer 123 of the gate structure 133. The polysilicon gate layer 123 and the metal layer 190 are collaboratively formed as a metal/poly plate capacitor C₂. After a step of forming metal conductor lines is completed, the memory cell C_{ELL} of the first embodiment is fabricated.

Please refer to FIG. 1I, FIG. 1J and FIG. 1K again. The merged n-doped region 171 is connected to a source line SL. The merged n-doped region 172 is connected to a bit line BL. The metal layer 190 is connected to an assist line AG. The merged n-doped region 173 is connected to a control line CL.

As shown in FIG. 1L, the memory cell C_{ELL} includes a floating gate transistor M_{F}, a MOS capacitor C₁ and a metal/poly plate capacitor C₂. The first drain/source terminal of the floating gate transistor M_{F} is connected to the source line SL. The second drain/source terminal of the floating gate transistor M_{F} is connected to the bit line BL. The body terminal of the floating gate transistor M_{F} is connected to P-well region PW. The first terminal of the MOS capacitor C₁ is connected to the floating gate 123 of the floating gate transistor M_{F}. The second terminal of the MOS capacitor C₁ is connected to the control line CL, and the N-well region NW is also connected to the control line CL. The first terminal of the metal/poly plate capacitor C₂ is connected to the floating gate 123 of the floating gate transistor M_{F}. The second terminal of the metal/poly plate capacitor C₂ is connected to the assist line AG.

As mentioned above, the memory cell C_{ELL} of the first embodiment includes one transistors M_{F} and two capacitors C₁ and C₂. Consequently, the memory cell C_{ELL} may be referred to as a 1T2C memory cell. The MOS capacitor C₁ and the metal/poly plate capacitor C₂ are used as coupling capacitors. When the erase action is performed, no carriers can be transferred through the two coupling capacitors C₁ and C₂.

Please refer to FIG. 1J again. A first overlapping area between the gate structure 133 and the region A is (L_{F1}×W_{F1}). A second overlapping area between the gate structure 133 and the region B is (L_{F2}×W_{F2}). In a better case, the second overlapping area (L_{F2}×W_{F2}) can be designed to be at least three times greater than the first overlapping area (L_{F1}×W_{F1}). That is, (L_{F2}×W_{F2})>3(L_{F1}×W_{F1})□In this way, the voltage coupling ratio of the MOS capacitor C₁ can be improved.

In the region A, the shallower LDD regions 151, 152 are firstly formed by using the LV production procedure, and then the merged n-doped regions 172 and 172 are formed. Consequently, the floating gate transistor M_{F} with the shorter channel length L_{F1} (e.g., 0.35 μm) can be designed to reduce the layout area of the memory cell C_{ELL}.

Since the channel length L_{F1} of the floating gate transistor M_{F} is relatively shorter, the p-type pocket regions 181 and 182 are formed in the floating gate transistor M_{F} to prevent the floating gate transistor M_{F} from experiencing a short channel effect and to enable the memory cell C_{ELL} to operate normally.

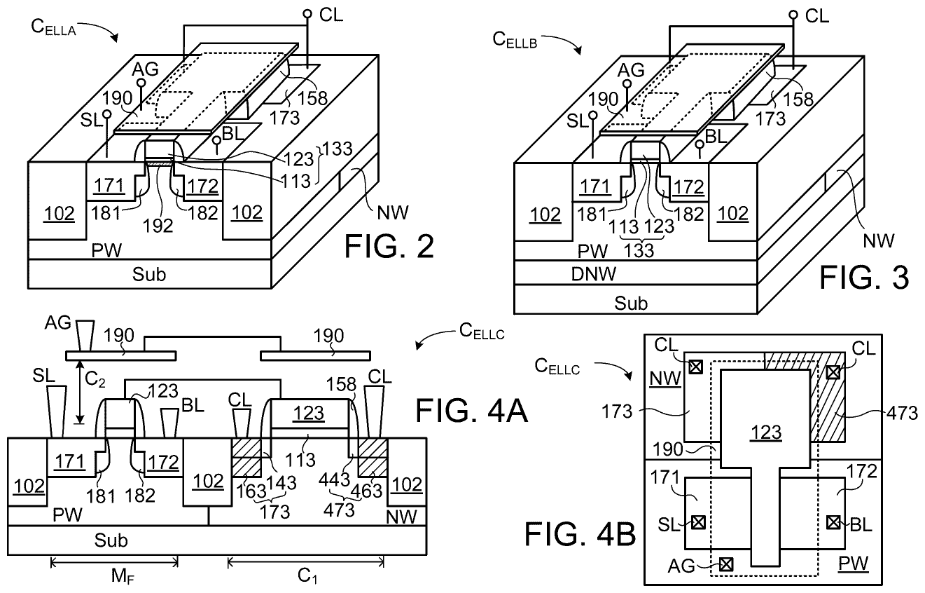

Furthermore, the structure of the memory cell C_{ELL} of the present invention may be further modified. For example, FIG. 2 is a schematic perspective view illustrating the structure of a memory cell according to a second embodiment of the present invention. In comparison with the memory cell C_{ELL} of the first embodiment, the memory cell C_{ELLA} of the second embodiment further includes a p-type channel 192 in region A. That is, a p-type channel implantation process is further performed to form the p-type channel 192 located between two merged n-doped regions 171 and 172 below the gate structure 133.

FIG. 3 is a schematic perspective view illustrating the structure of a memory cell according to a third embodiment of the present invention. In comparison with the memory cell C_{ELL} of the first embodiment, the memory cell C_{ELLB} of the third embodiment further includes a deep N-type region. For example, the deep N-type region is a deep N-well (DNW) region. The bottom side of the deep N-well region DNW is contacted with the semiconductor substrate Sub. The top side of the deep N-well (DNW) region is contacted with the N-well region NW and the P-well region PW. Alternatively, the deep N-type region can be an n-type buried layer (NBL).

FIG. 4A and FIG. 4B are a schematic cross-sectional view and a schematic top view illustrating the structure of a memory cell according to a fourth embodiment of the present invention. In comparison with the memory cell C_{ELL} of the first embodiment, more lightly doped drain processes (LDD process) and more ion implantation processes are performed to form a merged p-doped region 473 in the region B of the memory cell C_{ELLC}.

Please refer to FIG. 4A and FIG. 4B. In the region B, an n-LDD process in the MV production procedure is performed to form the n-LDD region 143, and an n-type ion implantation process in the MV production procedure is performed to form the n-type ion implantation regions 161. Consequently, the merged n-doped region 173 including the n-LDD region 143 and the n-type ion implantation region 163 is formed under the surface of the semiconductor substrate Sub and located beside a first side of the gate structure 133. Then, a p-LDD process in the MV production procedure is performed to form a p-LDD region 443, and a p-type ion implantation process in the MV production procedure is performed to form a p-type ion implantation region 463. Consequently, a merged p-doped region 473 including the p-LDD region 443 and the p-type ion implantation region 463 is formed under the surface of the semiconductor substrate Sub and located beside a second side of the gate structure 133.

After the step of connecting the control line CL to both the merged n-doped region 173 and the merged p-doped region 473, the memory cell C_{ELLC} of the fourth embodiment is fabricated.

The memory cells C_{ELL}, C_{ELLA}, C_{ELLB} and C_{ELLC} of the first embodiment to the fourth embodiment are all 1T2C memory cells. The equivalent circuits of the memory cell C_{ELLA}, C_{ELLB} and C_{ELLC} are similar to that of the memory cell C_{ELL} of the first embodiment, and are not redundantly described herein.

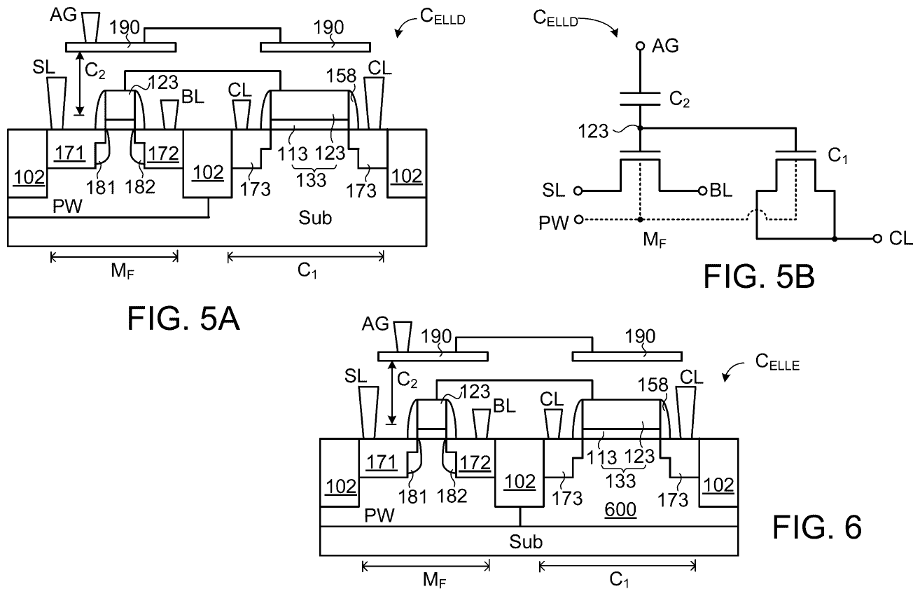

FIG. 5A and FIG. 5B are a schematic cross-sectional view and a schematic equivalent circuit diagram of a memory cell according to a fifth embodiment of the present invention. In comparison with the memory cell C_{ELL} of the first embodiment, the N-well region NW is not included in the memory cell C_{ELLD} of the fifth embodiment. That is to say, the second well region formed in the region B is the semiconductor substrate Sub, and the merged n-doped region 173 is formed in the semiconductor substrate Sub.

In the memory cell C_{ELLD} of the fifth embodiment, the semiconductor substrate Sub is a P-type semiconductor substrate. The gate structure 133, semiconductor substrate Sub and the merged n-doped region 173 are collaboratively formed as an n-type transistor. As shown in FIG. 5B, a gate terminal of the n-type transistor is connected to the floating gate 123 of the floating gate transistor M_{F}. The first drain/source terminal and the second drain/source terminal of n-type transistor are connected to the control line CL. The body terminal of the n-type transistor is connected to P-well region PW.

FIG. 6 is a schematic cross-sectional view of a memory cell according to a sixth embodiment of the present invention. In comparison with the memory cell C_{ELL} of the first embodiment, the N-well region NW is not included in the memory cell C_{ELLE} of the sixth embodiment. The second well region formed in the region B is a lightly p-type well region 600, and the merged n-doped region 173 is formed in the lightly p-type well region 600.

The memory cells C_{ELLD} and C_{ELLE} of the fifth embodiment and the sixth embodiment are all 1T2C memory cells, and the second well regions of the fifth embodiment and the sixth embodiment are P-type regions. The equivalent circuits of the memory cell C_{ELLE} of the sixth embodiment is similar to that of the memory cell C_{ELLD} of the fifth embodiment, and is not redundantly described herein.

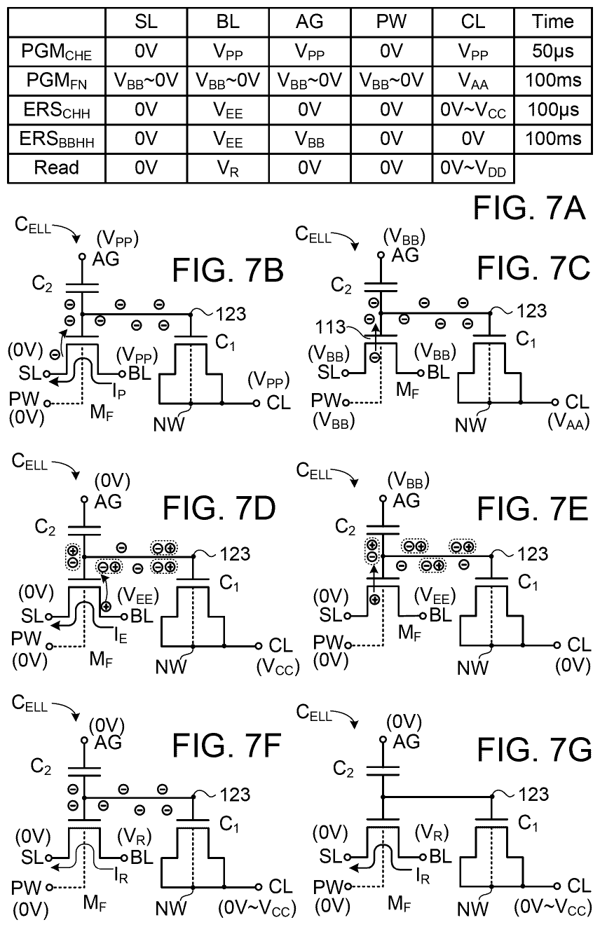

The present invention further provides various bias voltages suitable for memory cells, so that a program action, an erase action or a read action can be performed on the memory cells of the present invention. FIG. 7A is a bias voltage table illustrating the bias voltages for performing a program action, an erase action and a read action on the memory cell of the embodiments of the present invention. FIG. 7B and FIG. 7C are schematic circuit diagram of performing the program actions on the memory cell. FIG. 7D and FIG. 7E are schematic circuit diagrams of performing the erase action on the memory cell. FIGS. 7F and 7G are schematic circuit diagrams of performing the read action on the memory cell. There are two different program bias voltages used to perform the program action, and two different erase bias voltages used to perform the erase action. The following is an example of the memory cell C_{ELL} of the first embodiment to illustrate the program action, the erase action and the read action.

Please refer to FIG. 7A and FIG. 7B. When the program action (PGM_{CHE}) is performed, the source line SL receives a ground voltage (0V), the bit line BL receives a program voltage V_{PP}, the assist line AG receives the program voltage V_{PP}, the P-well region PW receives the ground voltage (0V), and the control line CL receives the program voltage V_{PP}. For Example, the program voltage V_{PP} is 7V and the program time is about 50 μs.

When the program action (PGM_{CHE}) is performed, the program voltage V_{PP} is coupled to the floating gate 123 through the MOS capacitor C₁ and a metal/poly plate capacitor C₂, so that the floating gate transistor M_{F} is turned on and a program current I_{P} is generated between the bit line BL and the source line SL. When the carriers (e.g., electrons) of the program current I_{P} flow through the channel region of the floating gate transistor M_{F}, a channel hot electron injection effect (also referred as a CHE effect) is generated. Since electrons are attracted by the voltages from the assist line AG and the control line CL, electrons are injected into the floating gate 123. Meanwhile, the storage state of the memory cell C_{ELL} is changed to a programmed state.

Please refer to FIG. 7A and FIG. 7C. When the program action (PGM_{FN}) is performed, the source line SL, the bit line BL, the assist line AG and the P-well region PW receive a voltage between a negative voltage V_{BB} and the ground voltage (0V), and the control line CL receives a positive voltage V_{AA}. According to the present invention, when the program action (PGM_{FN}) is performed, a voltage difference between the control line CL and the P-well region PW has to be greater than a tunneling voltage and the program time is about 100 ms. For example, the control line CL receives the positive voltage V_{AA}, the P-well region PW receives the negative voltage V_{BB}, the negative voltage V_{BB} is −7V, the positive voltage V_{AA} is +7V, and the tunneling voltage is 13.5V.

In another embodiment, when the program action (PGM_{FN}) is performed, the P-well region PW may receive the ground voltage (0V), the control line may the positive voltage V_{AA}, and the positive voltage V_{AA} is +14V. Consequently, the voltage difference between the control line CL and the P-well region PW is greater than the tunneling voltage.

When the program action (PGM_{FN}) is performed, the voltage difference between the control line CL and the P-well region PW is greater than the tunneling voltage, a Fowler-Nordheim tunneling effect (also referred as an FN tunneling effect) is generated in the floating gate transistor M_{F}. Due to the FN tunneling effect, electrons are transferred from P-well region PW to the floating gate 123 through the gate dielectric layer 113. Meanwhile, the storage state of the memory cell C_{ELL} is changed to a programmed state.

Please refer to FIG. 7A and FIG. 7D. When the erase action (ERS_{CHH}) is performed, the source line SL, the assist line AG and the P-well region PW receive the ground voltage (0V), the bit line BL receives an erase voltage V_{EE}, and the control line CL receives a voltage between a negative voltage V_{CC} and the ground voltage (0V). For example, the erase voltage V_{EE} is larger than or equal to the program voltage V_{PP}, the erase voltage V_{EE} is 7V, the negative voltage V_{CC} is −2V, and the erase time is about 100 μs.

When the erase action (ERS_{CHH}) is performed, the floating gate transistor M_{F} is turned on, and an erase current I_{E} is generated between the bit line BL and the source line SL. When the carriers (e.g., holes) of the erase current I_{E} flow through the pinch off point of the channel region of the floating gate transistor M_{F}, a channel hot hole injection effect (also referred as a CHH effect) is generated. Meanwhile, in the floating gate transistor M_{F}, electron-hole pairs are generated at the junction between the merged n-doped region and the P-well region PW. Consequently, the holes are injected into the floating gate 123. After electron-hole combination in the floating gate 123, the storage state of the memory cell C_{ELL} is changed to an erased state.

Please refer to FIG. 7A and FIG. 7E. When the erase action (ERS_{BBHH}) is performed, the source line SL, the P-well region PW, and the control line CL receive the ground voltage (0V), the bit line BL receives an erase voltage V_{EE}, and the assist line AG receives the negative voltage V_{BB}. For example, the erase voltage V_{EE} is +7V, the negative voltage V_{BB} is −7V, and the erase time is about 100 ms.

When the erase action (ERS_{BBHH}) is performed, the floating gate transistor M_{F} is turned off, the erase current I_{E} is not generated between the bit line BL and the source line SL. Meanwhile, in the floating gate transistor M_{F}, electron-hole pairs are generated at the junction between the merged n-doped region and the P-well region PW, and a band-to-band hot hole injection effect (also referred as a BBHH effect) is generated. Consequently, the holes are injected into the floating gate 123. After electron-hole combination in the floating gate 123, the storage state of the memory cell C_{ELL} is changed to an erased state.

Please refer to FIG. 7A, FIG. 7F and FIG. 7G. When the read action (Read) is performed, the source line SL, the assist line AG and the P-well region PW receive the ground voltage (0V), the bit line BL receives a read voltage V_{R}, and the control line CL receives a voltage between the ground voltage (0V) and a positive voltage V_{DD}. For example, the positive voltage V_{DD} is equal to the read voltage V_{R}, the read voltage V_{R} is 2.5V. The program voltage V_{PP} is higher than the read voltage V_{R}. The read voltage V_{R} is higher than the ground voltage (0V).

When the read action is performed, a read current I_{R} is generated between the bit line BL and the source line SL. The storage state of the memory cell can be determined according to the magnitude of the read current I_{R}. For example, in case that electrons are stored in the floating gate 123 as shown in FIG. 7F, the floating gate transistor M_{F} can hardly be turned on, and the magnitude of the read current I_{R} is very low (e.g., nearly zero). Consequently, it is determined that the memory cell C_{ELL} is in the programmed state. Whereas, in case that no electrons are stored in the floating gate 123 as shown in FIG. 7G, the floating gate transistor M_{F} is turned on, and the magnitude of the read current I_{R} is higher. Consequently, it is determined that the memory cell C_{ELL} is in the erased state.

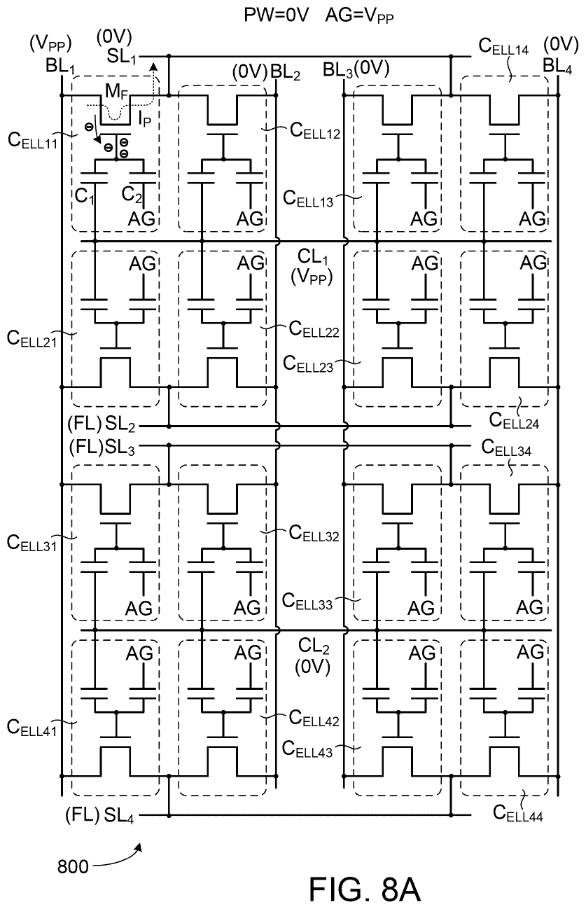

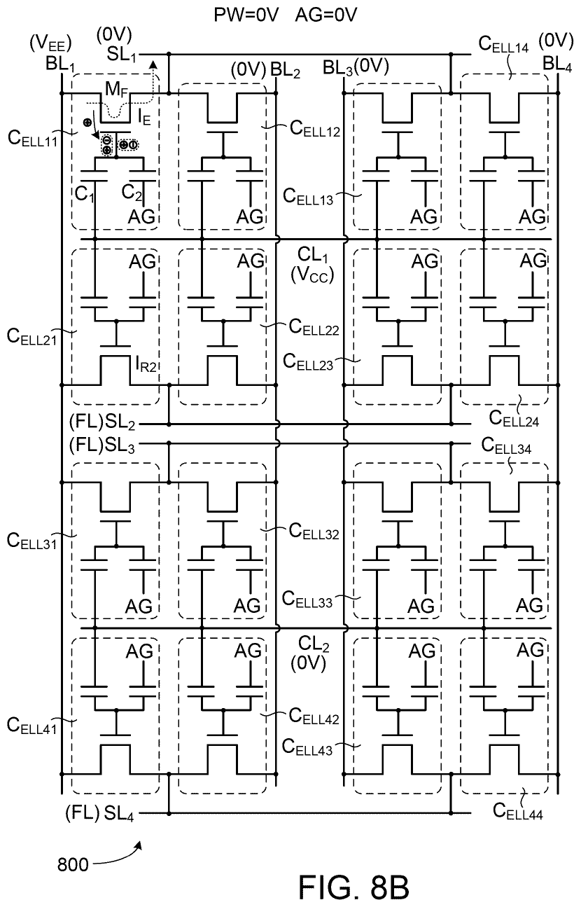

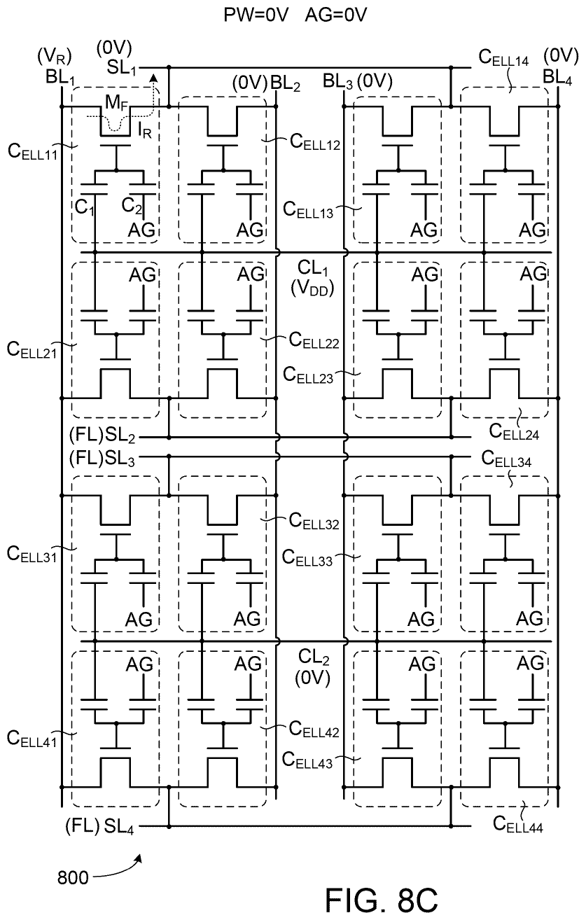

In addition, a variety of memory cell arrays can be formed using the memory cells of the present invention. Please refer to FIG. 8A, it is a schematic circuit diagram illustrating a first example of a memory cell array. The memory cell array 800 comprises 4×4 memory cells C_{ELL11}˜C_{ELL44}, each memory cell having the same structure. In some embodiments, the memory cell array 800 may comprise M×N memory cells, and M and N are positive integers.

The memory cell C_{ELL11} is a 1T2C memory cell having four terminals. The memory cell C_{ELL11} includes a floating gate transistor M_{F}, a MOS capacitor C₁, and a plate capacitor C₂. A first drain/source terminal of the floating gate transistor M_{F} serves as the first terminal of the memory cell C_{ELL11} and is connected to the source line SL₁. A second drain/source terminal of the floating gate transistor M_{F} serves as the second terminal of the memory cell C_{ELL11} and is connected to the bit line BL₁. A first terminal of the MOS capacitor C₁ is connected to the floating gate of the floating gate transistor M_{F}. A second terminal of the MOS capacitor C₁ serves as a third terminal of the memory cell C_{ELL11} and is connected to the control line CL₁. A first terminal of the plate capacitor C₂ is connected to the floating gate of the floating gate transistor M_{F}. A second terminal of the plate capacitor C₂ serves as a fourth terminal of the memory cell C_{ELL11} and is connected to the assist line AG. In addition, the other memory cells C_{ELL12} to C_{ELL44} in the memory cell array 800 have the same structure as the memory cell C_{ELL11}. The connection relationship inside the memory cells C_{ELL12}˜C_{ELL44} will not be described here. Only the connection relationship of the memory cell array 800 will be introduced.

In the memory cell array 800, the first terminals of the memory cells C_{ELL11}, C_{ELL12}, C_{ELL13} and C_{ELL14} are connected to the source line SL₁. The first terminals of the memory cells C_{ELL21}, C_{ELL22}, C_{ELL23} and C_{ELL24} are connected to the source line SL₂. The first terminals of the memory cells C_{ELL31}, C_{ELL32}, C_{ELL33} and C_{ELL34} are connected to the source line SL₃. The first terminals of the memory cells C_{ELL41}, C_{ELL42}, C_{ELL43} and C_{ELL44} are connected to the source line SL₄. The second terminals of the memory cells C_{ELL11}, C_{ELL21}, C_{ELL31} and C_{ELL41} are connected to the bit line BL₁. The second terminals of the memory cells C_{ELL12}, C_{ELL22}, C_{ELL32} and C_{ELL42} are connected to the bit line BL₂. The second terminals of the memory cells C_{ELL13}, C_{ELL23}, C_{ELL33} and C_{ELL43} are connected to the bit line BL₃. The second terminals of the memory cells C_{ELL14}, C_{ELL24}, C_{ELL34} and C_{ELL44} are connected to the bit line BL₄. The third terminals of the memory cells C_{ELL11}, C_{ELL12}, C_{ELL13} and C_{ELL14}, C_{ELL21}, C_{ELL22}, C_{ELL23} and C_{ELL24} are connected to the control line CL₁. The third terminals of the memory cells C_{ELL31}, C_{ELL32}, C_{ELL33} and C_{ELL34}, C_{ELL41}, C_{ELL42}, C_{ELL43} and C_{ELL44} are connected to the control line CL₂. The fourth terminals of all memory cells C_{ELL11}˜C_{ELL44} are connected to the assist line AG.

Furthermore, the program action, the erase action and the read action can be performed on any memory cell C_{ELL11}˜C_{ELL44} of the memory cell array 800. In the following description, the memory cell C_{ELL11} is the selected memory cell, and program action, the erase action and the read action are performed on the selected memory cell.

As shown in FIG. 8A, it also shows the bias voltages for performing the program action on the memory cell array of the first example. During the program action, the source line SL₁ receives the ground voltage (0V), and the other source lines SL₂˜SL₄ are in the floating state (FL). The bit line BL₁ receives the program voltage V_{PP}, and the other bit lines BL₂˜BL₄ receive the ground voltage (0V). The control line CL₁ receives the program voltage V_{PP}, and the control line CL₂ receives the ground voltage (0V). Furthermore, the P-well region PW receives the ground voltage (0V), and the assist line AG receives the program voltage V_{PP}. Consequently, in the memory cell array 800, the memory cell C_{ELL11} is the selected memory cell and the other memory cells C_{ELL12}˜C_{ELL44} are unselected memory cell.

In the selected memory cell C_{ELL11}, the floating gate transistor M_{F} is turned on, a program current I_{P} is generated between the bit line BL₁ and the source line SL₁, and a channel hot electron injection effect (also referred as a CHE effect) is generated. Consequently, the storage state of the selected memory cell C_{ELL11} is changed to a programmed state.

Please refer to FIG. 8B, it shows the bias voltages for performing the erase action on the memory cell array of the first example. During the erase action, the source line SL₁ receives the ground voltage (0V), and the other source lines SL₂˜SL₄ are in the floating state (FL). The bit line BL₁ receives the erase voltage V_{EE}, and the other bit lines BL₂˜BL₄ receive the ground voltage (0V). The control line CL₁ receives the negative voltage V_{CC}, and the control line CL₂ receives the ground voltage (0V). Furthermore, the P-well region PW and the assist line AG receive the ground voltage (0V). Consequently, in the memory cell array 800, the memory cell C_{ELL11} is the selected memory cell and the other memory cells C_{ELL12}˜C_{ELL44} are unselected memory cell.

In the selected memory cell C_{ELL11}, the floating gate transistor M_{F} is turned on, an erase current I_{E} is generated between the bit line BL₁ and the source line SL₁, and a channel hot hole injection effect (also referred as a CHH effect) is generated. Consequently, the storage state of the selected memory cell C_{ELL11} is changed to an erased state.

Please refer to FIG. 8C, it shows the bias voltages for performing the read action on the memory cell array of the first example. During the read action, the source line SL₁ receives the ground voltage (0V), and the other source lines SL₂˜SL₄ are in the floating state (FL). The bit line BL₁ receives the read voltage V_{R}, and the other bit lines BL₂˜BL₄ receive the ground voltage (0V). The control line CL₁ receives the positive voltage V_{DD}, and the control line CL₂ receives the ground voltage (0V). Furthermore, the P-well region PW and the assist line AG receive the ground voltage (0V). Consequently, in the memory cell array 800, the memory cell C_{ELL11} is the selected memory cell and the other memory cells C_{ELL12}˜C_{ELL44} are unselected memory cell.

In the selected memory cell C_{ELL11}, the floating gate transistor M_{F} is turned on, a read current I_{R} is generated between the bit line BL₁ and the source line SL₁. Consequently, the storage state of the selected memory cell C_{ELL11} is determined according to the magnitude of the read current I_{R}.

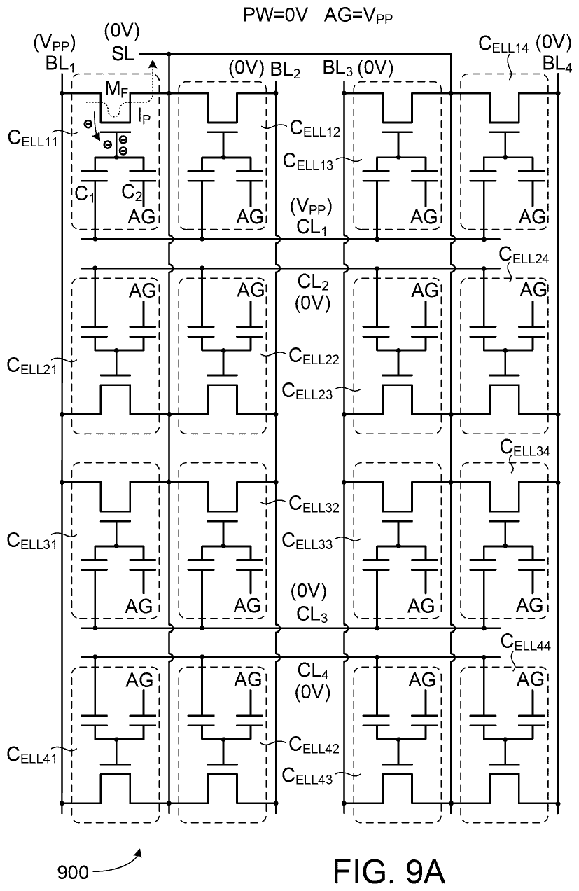

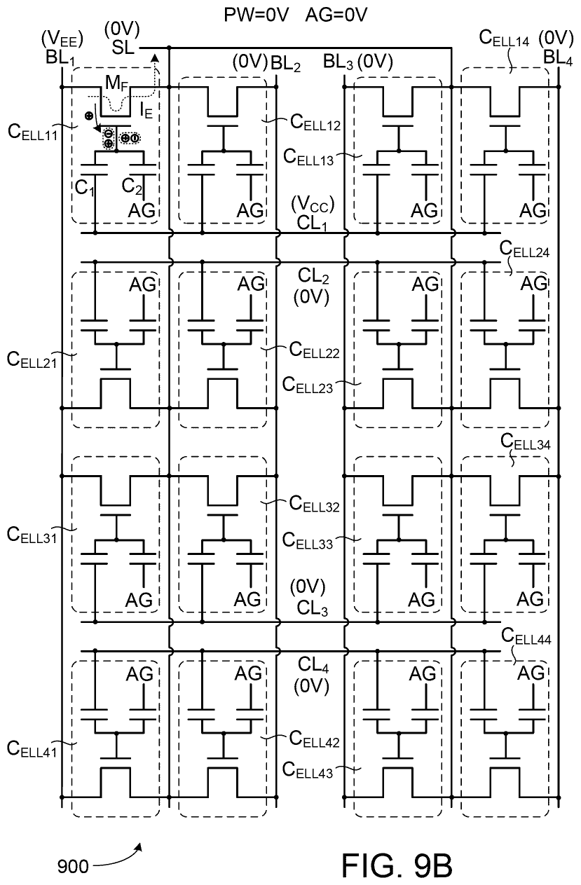

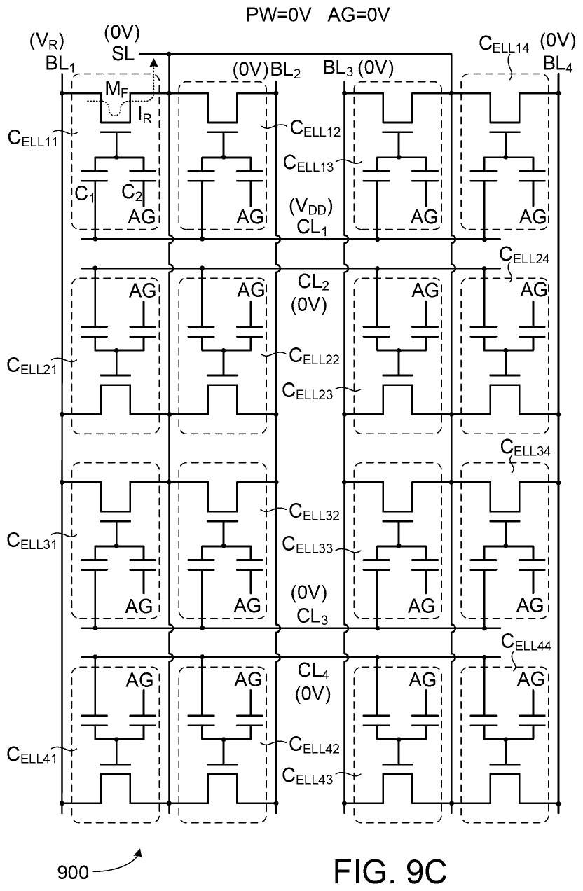

Please refer to FIG. 9A, it is a schematic circuit diagram illustrating a second example of a memory cell array. The memory cell array 900 comprises 4×4 memory cells C_{ELL11}˜C_{ELL44}, each memory cell having the same structure. In some embodiments, the memory cell array 900 may comprise M×N memory cells, and M and N are positive integers.

Similarly, the memory cell C_{ELL11} is a 1T2C memory cell having four terminals. In the memory cell array 900, the first terminals of all memory cells C_{ELL11}˜C_{ELL44} are connected to the source line SL. The second terminals of the memory cells C_{ELL11}, C_{ELL21}, C_{ELL31} and C_{ELL41} are connected to the bit line BL₁. The second terminals of the memory cells C_{ELL12}, C_{ELL22}, C_{ELL32} and C_{ELL42} are connected to the bit line BL₂. The second terminals of the memory cells C_{ELL13}, C_{ELL23}, C_{ELL33} and C_{ELL43} are connected to the bit line BL₃. The second terminals of the memory cells C_{ELL14}, C_{ELL24}, C_{ELL34} and C_{ELL44} are connected to the bit line BL₄. The third terminals of the memory cells C_{ELL11}, C_{ELL12}, C_{ELL13} and C_{ELL14} are connected to the control line CL₁. The third terminals of the memory cells C_{ELL21}, C_{ELL22}, C_{ELL23} and C_{ELL24} are connected to the control line CL₂. The third terminals of the memory cells C_{ELL31}, C_{ELL32}, C_{ELL33} and C_{ELL34} are connected to the control line CL₃. The third terminals of the memory cells C_{ELL41}, C_{ELL42}, C_{ELL43} and C_{ELL44} are connected to the control line CL₄. The fourth terminals of all memory cells C_{ELL11}˜C_{ELL44} are connected to the assist line AG.

Furthermore, the program action, the erase action and the read action can be performed on any memory cell C_{ELL11}˜C_{ELL44} of the memory cell array 900. In the following description, the memory cell C_{ELL11} is the selected memory cell, and program action, the erase action and the read action are performed on the selected memory cell.

As shown in FIG. 9A, it also shows the bias voltages for performing the program action on the memory cell array of the second example. During the program action, the source line SL receives the ground voltage (0V). The bit line BL₁ receives the program voltage V_{PP}, and the other bit lines BL₂˜BL₄ receive the ground voltage (0V). The control line CL₁ receives the program voltage V_{PP}, and the other control line CL₂˜CL₄ receive the ground voltage (0V). Furthermore, the P-well region PW receives the ground voltage (0V), and the assist line AG receives the program voltage V_{PP}. Consequently, in the memory cell array 900, the memory cell C_{ELL11} is the selected memory cell and the other memory cells C_{ELL12}˜C_{ELL44} are unselected memory cell.

In the selected memory cell C_{ELL11}, the floating gate transistor M_{F} is turned on, a program current I_{P} is generated between the bit line BL₁ and the source line SL, and a channel hot electron injection effect (also referred as a CHE effect) is generated. Consequently, the storage state of the selected memory cell C_{ELL11} is changed to a programmed state.

Please refer to FIG. 9B, it shows the bias voltages for performing the erase action on the memory cell array of the second example. During the erase action, the source line SL receives the ground voltage (0V). The bit line BL₁ receives the erase voltage V_{EE}, and the other bit lines BL₂˜BL₄ receive the ground voltage (0V). The control line CL₁ receives the negative voltage V_{CC}, and the other control line CL₂˜CL₄ receive the ground voltage (0V). Furthermore, the P-well region PW and the assist line AG receive the ground voltage (0V). Consequently, in the memory cell array 900, the memory cell C_{ELL11} is the selected memory cell and the other memory cells C_{ELL12}˜C_{ELL44} are unselected memory cell.

In the selected memory cell C_{ELL11}, the floating gate transistor M_{F} is turned on, an erase current I_{E} is generated between the bit line BL₁ and the source line SL, and a channel hot hole injection effect (also referred as a CHH effect) is generated. Consequently, the storage state of the selected memory cell C_{ELL11} is changed to an erased state.

Please refer to FIG. 9C, it shows the bias voltages for performing the read action on the memory cell array of the second example. During the read action, the source line SL receives the ground voltage (0V). The bit line BL₁ receives the read voltage V_{R}, and the other bit lines BL₂˜BL₄ receive the ground voltage (0V). The control line CL₁ receives the positive voltage V_{DD}, and the other control line CL₂˜CL₄ receive the ground voltage (0V). Furthermore, the P-well region PW and the assist line AG receive the ground voltage (0V). Consequently, in the memory cell array 900, the memory cell C_{ELL11} is the selected memory cell and the other memory cells C_{ELL12}˜C_{ELL44} are unselected memory cell.

In the selected memory cell C_{ELL11}, the floating gate transistor M_{F} is turned on, a read current I_{R} is generated between the bit line BL₁ and the source line SL. Consequently, the storage state of the selected memory cell C_{ELL11} is determined according to the magnitude of the read current I_{R}.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An erasable programmable non-volatile memory comprising a first memory cell, wherein the first memory cell comprises:
a semiconductor substrate;
an isolation structure formed on the semiconductor substrate, wherein a surface of the semiconductor substrate is divided into a first region and a second region by the isolation structure;
a first well region formed under a surface of the first region of the semiconductor substrate;
a second well region formed under a surface of the second region of the semiconductor substrate;
a gate structure formed on the surface of the first region and the surface of the second region;
a spacer formed on a sidewall of the gate structure;
a first merged doped region formed under the surface of the first region, wherein the first merged doped region is located beside a first side of the gate structure;
a second merged doped region formed under the surface of the first region, wherein the second merged doped region is located beside a second side of the gate structure;
a first pocket region formed in the first well region, wherein the first pocket is contacted with the first merged doped region;
a second pocket region formed in the first well region, wherein the second pocket is contacted with the second merged doped region, and the first pocket region and the second pocket region are located between the first merged doped region and the second merged doped region;
a third merged doped region formed under the surface of the second region;
a metal layer formed over the gate structure, wherein a vertical projection area of the metal layer covers the gate structure;
a first source line electrically connected with the first merged doped region;
a first bit line electrically connected with the second merged doped region;
a first control line electrically connected with the third merged doped region;
an assist line connected with the metal layer;
a first MOS capacitor, wherein a first terminal of the first MOS capacitor is electrically connected with the gate structure, and a second terminal of the first MOS capacitor is electrically connected with first control line; and
a first plate capacitor, wherein a first terminal of the first plate capacitor is electrically connected with the gate structure, and a second terminal of the first plate capacitor is electrically connected with the assist line,
wherein the first merged doped region, the gate structure and the second merged doped region are collaboratively formed as a first floating gate transistor; the gate structure and the third merged doped region are collaboratively formed as the first MOS capacitor; and the gate structure and the metal layer are collaboratively formed as the first plate capacitor.

2. The erasable programmable non-volatile memory as claimed in claim 1, wherein there is a first overlapping area between the gate structure and the first region, and there is a second overlapping area between the gate structure and the second region, wherein the second overlapping area is at least three times greater than the first overlapping area.

3. The erasable programmable non-volatile memory as claimed in claim 1, wherein the first merged doped region comprises a first ion implantation region and a first lightly doped drain region, the second merged doped region comprises a second ion implantation region and a second lightly doped drain region, and the third merged doped region comprises a third ion implantation region and a third lightly doped drain region; wherein the first lightly doped drain region is located beside the first side of the gate structure and under the spacer, the second lightly doped drain region is located beside the second side of the gate structure and under the spacer, and the third lightly doped drain region is located beside the gate structure and under the spacer.

4. The erasable programmable non-volatile memory as claimed in claim 3, wherein a doping depth of the first lightly doped drain region and a doping depth of the second lightly doped drain region are equal, and the doping depth of the first lightly doped drain region is shallower than a doping depth of the third lightly doped drain region.

5. The erasable programmable non-volatile memory as claimed in claim 4, wherein a doping concentration of the first lightly doped drain region and a doping concentration of the second lightly doped drain region are equal, and a doping concentration of the third lightly doped drain region is less than the doping concentration of the first lightly doped drain region.

6. The erasable programmable non-volatile memory as claimed in claim 1, wherein the semiconductor substrate is a P-type semiconductor substrate, the first well region is a P-well region, the second well region is an N-well region, the first merged doped region is a first merged n-doped region, the second merged doped region is a second merged n-doped region, the third merged doped region is a third merged n-doped region, the first pocket region is a first p-type pocket region, and the second pocket region is a second p-type pocket region.

7. The erasable programmable non-volatile memory as claimed in claim 6, wherein the first memory cell further comprises a p-type channel located between the first merged n-doped region and the second merged n-doped region below the gate structure.

8. The erasable programmable non-volatile memory as claimed in claim 6, wherein the first memory cell further comprises a deep N-type region, wherein a bottom side of the deep N-type region is in contact with the P-type semiconductor substrate, and a top side of the deep N-type region is in contact with the P-well region and the N-well region.

9. The erasable programmable non-volatile memory as claimed in claim 8, wherein the deep N-type region is a deep N-well region or an n-type buried layer.

10. The erasable programmable non-volatile memory as claimed in claim 6, wherein the first memory cell further comprises a merged p-doped region formed under the surface of the second region, wherein the first control line is electrically connected with the merged p-doped region.

11. The erasable programmable non-volatile memory as claimed in claim 1, wherein the semiconductor substrate is a P-type semiconductor substrate, the first well region is a P-well region, the second well region is a P-type region, the first merged doped region is a first merged n-doped region, the second merged doped region is a second merged n-doped region, the third merged doped region is a third merged n-doped region, the first pocket region is a first p-type pocket region, and the second pocket region is a second p-type pocket region.

12. The erasable programmable non-volatile memory as claimed in claim 11, wherein the second well region is a lightly p-type well region.

13. The erasable programmable non-volatile memory as claimed in claim 1, wherein the first floating gate transistor is an n-type floating gate transistor, a first drain/source terminal of the first floating gate transistor is connected to the first source line, a second drain/source terminal of the first floating gate transistor is connected to the first bit line, a body terminal of the first floating gate transistor is connected to a P-well region, the first terminal of the first MOS capacitor is connected to a floating gate of the first floating gate transistor, the second terminal of the first MOS capacitor is connected to the first control line, the first terminal of the first plate capacitor is connected to the floating gate of the first floating gate transistor, and the second terminal of the first plate capacitor is connected to the assist line.

14. The erasable programmable non-volatile memory as claimed in claim 13, wherein when a program action is performed on the first memory cell, the first source line receives a ground voltage, the first bit line receives a program voltage, the assist line receives the program voltage, the P-well region receives the ground voltage, the first control line receives the program voltage; wherein when the program action is performed, a channel hot electron injection effect is generated, electrons are injected into the floating gate of the first floating gate transistor, and a storage state of the first memory cell is changed to a programmed state.

15. The erasable programmable non-volatile memory as claimed in claim 13, wherein when a program action is performed on the first memory cell, the first source line, the first bit line, the assist line and the P-well region receive a voltage between a negative voltage and a ground voltage, the first control line receives a positive voltage; wherein a voltage difference between the first control line and the P-well region is greater than a tunneling voltage; wherein when the program action is performed, a Fowler-Nordheim tunneling effect is generated, electrons are injected into the floating gate of the first floating gate transistor, and a storage state of the first memory cell is changed to a programmed state.

16. The erasable programmable non-volatile memory as claimed in claim 13, wherein when an erase action is performed on the first memory cell, the first source line receives a ground voltage, the first bit line receives an erase voltage, the assist line receives the ground voltage, the P-well region receives the ground voltage, the first control line receives a voltage between a negative voltage and the ground voltage; wherein when the erase action is performed, a channel hot hole injection effect is generated, holes are injected into the floating gate of the first floating gate transistor, and a storage state of the first memory cell is changed to an erased state.

17. The erasable programmable non-volatile memory as claimed in claim 13, wherein when an erase action is performed on the first memory cell, the first source line, the P-well region and the first control line receive a ground voltage, the first bit line receives a erase voltage, the assist line receives a negative voltage; wherein when the erase action is performed, a band-to-band hot hole injection effect is generated, holes are injected into the floating gate of the first floating gate transistor, and a storage state of the first memory cell is changed to an erased state.

18. The erasable programmable non-volatile memory as claimed in claim 13, further comprising a second memory cell, wherein the second memory cell comprises:
a second floating gate transistor, wherein a first drain/source terminal of the second floating gate transistor is connected to the first source line, and a second drain/source terminal of the second floating gate transistor is connected to a second bit line;
a second MOS capacitor, wherein a first terminal of the second MOS capacitor is connected to a floating gate of the second floating gate transistor, and a second terminal of the second MOS capacitor is connected to the first control line; and
a second plate capacitor, wherein a first terminal of the second plate capacitor is connected to the floating gate of the second floating gate transistor, and a second terminal of the second plate capacitor is connected to the assist line.

19. The erasable programmable non-volatile memory as claimed in claim 18, further comprising a third memory cell, wherein the third memory cell comprises:
a third floating gate transistor, wherein a first drain/source terminal of the third floating gate transistor is connected to a second source line, and a second drain/source terminal of the third floating gate transistor is connected to the first bit line;
a third MOS capacitor, wherein a first terminal of the third MOS capacitor is connected to a floating gate of the third floating gate transistor, and a second terminal of the third MOS capacitor is connected to the first control line; and
a third capacitor, wherein a first terminal of the third capacitor is connected to the floating gate of third floating gate transistor, and a second terminal of the third plate capacitor is connected to the assist line.

20. The erasable programmable non-volatile memory as claimed in claim 13, further comprising a second memory cell, wherein the second memory cell comprises:
a second floating gate transistor, wherein a first drain/source terminal of the second floating gate transistor is connected to the first source line, and a second drain/source terminal of the second floating gate transistor is connected to the first bit line;
a second MOS capacitor, wherein a first terminal of the second MOS capacitor is connected to a floating gate of the second floating gate transistor, and a second terminal of the second MOS capacitor is connected to a second control line; and
a second plate capacitor, wherein a first terminal of the second plate capacitor is connected to the floating gate of the second floating gate transistor, and a second terminal of the second plate capacitor is connected to the assist line.

21. The erasable programmable non-volatile memory as claimed in claim 20, further comprising a third memory cell, wherein the third memory cell comprises:
a third floating gate transistor, wherein a first drain/source terminal of the third floating gate transistor is connected to the first source line, and a second drain/source terminal of the third floating gate transistor is connected to a second bit line;
a third MOS capacitor, wherein a first terminal of the third MOS capacitor is connected to a floating gate of the third floating gate transistor, and a second terminal of the third MOS capacitor is connected to the first control line; and
a third capacitor, wherein a first terminal of the third capacitor is connected to the floating gate of third floating gate transistor, and a second terminal of the third plate capacitor is connected to the assist line.
